(19) United States
(12) Patent Application Publication
(10) Pub. No.: US 2024/0347475 A1
(43) Pub. Date: Oct. 17, 2024

(54) INTEGRATED DEVICE PACKAGE WITH METAL CLIP FOR STACKING ELECTRONIC COMPONENTS

(71) Applicant: Skyworks Solutions, Inc., Irvine, CA (US)

(72) Inventor: Andrew Christopher Laib, Newark, CA (US)

(21) Appl. No.: 18/621,909

(22) Filed: Mar. 29, 2024

Related U.S. Application Data
(60) Provisional application No. 63/495,962, filed on Apr. 13, 2023.
(60) Provisional application No. 63/495,851, filed on Apr. 13, 2023.

(51) Int. Cl. H01L 23/552; H01L 23/00; H01L 23/492

(52) U.S. Cl. CPC H01L 23/552; H01L 23/492; H01L 24/16; H01L 24/32; H01L 24/48; H01L 24/73; H01L 2224/16227; H01L 2224/32225; H01L 2224/48227; H01L 2224/73265

(57) ABSTRACT

An integrated device package is disclosed. The integrated device package can include a surface mount technology component that is flip-chip mounted to a carrier. The surface mount technology component can be a gallium arsenide die or a bulk acoustic wave filter. The carrier can be a printed circuit board. The integrated device package can include a metal clip that has a first portion at least partially disposed over the surface mount technology component and a second portion coupled to the carrier. The first portion and the surface mount technology component are spaced apart by a gap. The integrated device package can include an electronic component that is mounted to the first portion of the metal clip.

### CROSS REFERENCE TO PRIORITY APPLICATION

Any and all applications for which a foreign or domestic priority claim is identified in the Application Data Sheet as filed with the present application, including U.S. Provisional Patent Application No. 63/495,962, filed Apr. 13, 2023 and titled “INTEGRATED DEVICE PACKAGE WITH METAL CLIP FOR STACKING ELECTRONIC COMPONENT OVER SENSITIVE COMPONENT,” and U.S. Provisional Patent Application No. 63/495,851, filed Apr. 13, 2023 and titled “METAL CLIP IN INTEGRATED DEVICE PACKAGE FOR GROUNDING AND ELECTROMAGNETIC SHIELDING,” are hereby incorporated by reference under 37 CFR 1.57 in their entirety.

### BACKGROUND

### Technical Field

The field relates to device packages, and in particular, to integrated device packages with a metal clip having a surface mount technology component such as a gallium arsenide (GaAs) die or a bulk acoustic wave (BAW) filter.

### Description of Related Technology

An integrated device package can include an electrical component, such as a surface mount technology (SMT) component that is mounted on a carrier. The SMT component can include an integrated device die (e.g., microelectronicmechanical systems (MEMS) die or an application specific integrated circuit (ASIC)) or an acoustic wave filter. Some SMT components can be sensitive, for example, to external pressure. A bulk acoustic wave (BAW) filter is an example of a sensitive SMT component. Acoustic wave filters can be implemented in radio frequency electronic systems. For instance, filters in a radio frequency front end of a mobile phone can include acoustic wave filters.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to an integrated device package including: a surface mount technology component flip-chip mounted to a carrier; a metal clip having a first portion at least partially disposed over the surface mount technology component and a second portion coupled to the carrier, the first portion and the surface mount technology component spaced apart by a gap; and an electronic component mounted to the first portion of the metal clip.

In some embodiments, the techniques described herein relate to an integrated device package wherein the surface mount technology component is a gallium arsenide die or a bulk acoustic wave filter.

In some embodiments, the techniques described herein relate to an integrated device package wherein the carrier is a printed circuit board.

In some embodiments, the techniques described herein relate to an integrated device package wherein the gap between the first portion and the surface mount technology component is in a range of 10 μm to 200 μm.

In some embodiments, the techniques described herein relate to an integrated device package wherein the metal clip is connected to a ground.

In some embodiments, the techniques described herein relate to an integrated device package wherein the metal clip is an electromagnetic shield configured to shield the surface mount technology component from electromagnetic fields.

In some embodiments, the techniques described herein relate to an integrated device package wherein the metal clip is a copper clip.

In some embodiments, the techniques described herein relate to an integrated device package wherein the first portion and the second portion are unitary formed.

In some embodiments, the techniques described herein relate to an integrated device package wherein the electronic component is mounted to the first portion of the metal clip by way of a die mount paste, a die attach film, or a conductive die attach film such that the first portion is positioned between the surface mount technology component and the electronic component.

In some embodiments, the techniques described herein relate to an integrated device package wherein the electronic component is wire bonded to the carrier.

In some embodiments, the techniques described herein relate to an integrated device package further including a second electronic component mounted to the first portion of the metal clip.

In some aspects, the techniques described herein relate to an integrated device package including: a bulk acoustic wave filter mounted to a carrier; a metal clip having a first portion at least partially disposed over the bulk acoustic wave filter and second portion coupled to the carrier, the first portion and the bulk acoustic wave filter spaced apart by a gap; and an electronic component mounted to the first portion of the metal clip.

In some embodiments, the techniques described herein relate to an integrated device package wherein the bulk acoustic wave filter is flip-chip mounted to the carrier.

In some embodiments, the techniques described herein relate to an integrated device package wherein the carrier is a printed circuit board.

In some embodiments, the techniques described herein relate to an integrated device package wherein the gap between the first portion and the bulk acoustic wave filter is in a range of 10 μm to 200 μm.

In some embodiments, the techniques described herein relate to an integrated device package wherein the first portion and the second portion are unitary formed.

In some aspects, the techniques described herein relate to an integrated device package including: a surface mount technology component mounted to a printed circuit board; a metal clip having a first portion at least partially disposed over the surface mount technology component and a second portion coupled to the printed circuit board, the first portion and the surface mount technology component spaced apart by a gap; and an electronic component mounted to the first portion of the metal clip.

In some embodiments, the techniques described herein relate to an integrated device package wherein the surface mount technology component is a bulk acoustic wave filter that is flip-chip mounted to the printed circuit board.

In some embodiments, the techniques described herein relate to an integrated device package wherein the gap between the first portion and the surface mount technology component is in a range of 10 μm to 200 μm.

In some embodiments, the techniques described herein relate to an integrated device package wherein the first portion and the second portion are unitary formed.

In some aspects, the techniques described herein relate to an integrated device package including: a surface mount technology component flip-chip mounted to a carrier; a metal clip having a first portion at least partially disposed over the surface mount technology component and second portion coupled to a ground connection of the carrier; and an electronic component mounted to the first portion of the metal clip, the electronic component being grounded at least partially through the metal clip.

In some embodiments, the techniques described herein relate to an integrated device package wherein the metal clip is an electromagnetic shield configured to shield the surface mount technology component from electromagnetic fields.

In some embodiments, the techniques described herein relate to an integrated device package wherein surface mount technology component includes a lower side facing the carrier, an upper side opposite the lower side, a first sidewall extends between the lower side and the upper side, and a second sidewall opposite the first sidewall, the second portion of the metal clip includes a first leg disposed adjacent to the first sidewall and a second leg disposed adjacent to the second sidewall.

In some embodiments, the techniques described herein relate to an integrated device package wherein the metal clip is electrically isolated from the surface mount technology component.

In some embodiments, the techniques described herein relate to an integrated device package wherein the metal clip is spaced apart from the surface mount technology component by a gap.

In some embodiments, the techniques described herein relate to an integrated device package wherein the metal clip is in physical contact with the surface mount technology component.

In some embodiments, the techniques described herein relate to an integrated device package wherein the electronic component is mounted to the first portion of the metal clip by way of a conductive adhesive.

In some embodiments, the techniques described herein relate to an integrated device package wherein the surface mount technology component is a gallium arsenide die or a bulk acoustic wave filter.

In some aspects, the techniques described herein relate to an integrated device package including: a bulk acoustic wave filter mounted to a carrier; a metal clip having a first portion at least partially disposed over the bulk acoustic wave filter and second portion coupled to a ground connection of the carrier, the metal clip electrically isolated from the bulk acoustic wave filter; and an electronic component mounted to the first portion of the metal clip.

In some embodiments, the techniques described herein relate to an integrated device package wherein the electronic component is mounted to the first portion of the metal clip by way of a conductive adhesive, and the electronic component is grounded at least partially through the metal clip and the conductive adhesive.

In some embodiments, the techniques described herein relate to an integrated device package wherein the metal clip is an electromagnetic shield configured to shield the bulk acoustic wave filter from electromagnetic fields.

In some embodiments, the techniques described herein relate to an integrated device package wherein bulk acoustic wave filter includes a lower side facing the carrier, an upper side opposite the lower side, a first sidewall extends between the lower side and the upper side, and a second sidewall opposite the first sidewall, the second portion of the metal clip includes a first leg disposed adjacent to the first sidewall and a second leg disposed adjacent to the second sidewall.

In some embodiments, the techniques described herein relate to an integrated device package wherein the metal clip is spaced apart from the bulk acoustic wave filter by a gap.

In some embodiments, the techniques described herein relate to an integrated device package wherein the metal clip is in physical contact with the bulk acoustic wave filter.

In some aspects, the techniques described herein relate to an integrated device package including: a surface mount technology component flip-chip mounted to a carrier; a metal clip having a first portion at least partially disposed over the surface mount technology component and second portion coupled to the carrier, the metal clip being an electromagnetic shield configured to shield the surface mount technology component from electromagnetic fields; and an electronic component mounted to the first portion of the metal clip.

In some embodiments, the techniques described herein relate to an integrated device package wherein surface mount technology component includes a lower side facing the carrier, an upper side opposite the lower side, a first sidewall extends between the lower side and the upper side, and a second sidewall opposite the first sidewall, the second portion of the metal clip includes a first leg disposed adjacent to the first sidewall and a second leg disposed adjacent to the second sidewall.

In some embodiments, the techniques described herein relate to an integrated device package wherein the metal clip is spaced apart from the surface mount technology component by a gap.

In some embodiments, the techniques described herein relate to an integrated device package wherein the metal clip is in physical contact with the surface mount technology component.

In some embodiments, the techniques described herein relate to an integrated device package wherein the electronic component is mounted to the first portion of the metal clip by way of a conductive adhesive, and the electronic component is grounded at least partially through the metal clip and the conductive adhesive.

In some embodiments, the techniques described herein relate to an integrated device package wherein the surface mount technology component is a gallium arsenide die or a bulk acoustic wave filter.

The present disclosure relates to U.S. patent application Ser. No. ______ [Attorney Docket SKYWRKS.1470A2], titled “METAL CLIP IN INTEGRATED DEVICE PACKAGE FOR GROUNDING AND ELECTROMAGNETIC SHIELDING” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1 is a schematic cross-sectional side view of an integrated device package according to an embodiment.

FIG. 2 is a schematic to plan view of the integrated device package of FIG. 1.

FIG. 3 is a schematic to plan view of the integrated device package according to another embodiment.

FIG. 4 is a schematic to plan view of the integrated device package according to another embodiment.

FIGS. 5A-5D show a method or manufacturing the integrated device package of FIGS. 1 and 2.

FIG. 6 is a schematic cross-sectional side view of an integrated device package according to an embodiment.

FIG. 7 is a schematic cross-sectional side view of an integrated device package according to another embodiment.

FIG. 8 is a schematic diagram of a wireless communication device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

A surface mount technology (SMT) components can be mounted on a carrier, such as a printed circuit board (PCB). Certain SMT components can be sensitive to external force or pressure. For example, gallium arsenide (GaAs) dies and bulk acoustic wave (BAW) filters are examples of sensitive SMT components. Due to their sensitivity, it can be challenging to stack another component over the sensitive SMT components. Also, certain SMT components can be sensitive to electromagnetic (EM) fields. For example, microelectromechanical systems (MEMS) sensors and radio frequency components (e.g., BAW filters) are particularly sensitive to electromagnetic fields.

Various embodiments disclosed herein relate to structures of integrated device packages that enable an electronic component to stack over a sensitive surface mount technology (SMT) component. In some embodiments, an integrated device package can include a carrier, an SMT component that is flip-chip mounted to the carrier, a metal clip that is coupled to the carrier and at least partially disposed over the SMT component, an electronic component that is mounted to the metal clip. A portion of the metal clip that is at least partially disposed over the SMT component includes a plate portion. The metal clip can also include one or more legs that is coupled to the carrier and extends between the carrier and the plate portion. In some embodiments, the metal clip can be a copper (Cu) clip. In some embodiments, the SMT component can be a gallium arsenide (GaAs) die or a bulk acoustic wave (BAW) filter. The SMT component and the plate portion of the metal clip can be spaced by a gap. Therefore, in some embodiments, SMT component and the plate portion of the metal clip are not in physical contact with each other. The electronic component can be wire-bonded to the carrier. The electronic component can be mounted to the plate portion of the metal clip by way of a suitable material, such as a die mount paste, die attach film, or a conductive die attach film. Various embodiments disclosed herein relate to integrated device packages include an electromagnetic (EM) sensitive component that is flip-chip mounted to a carrier, a metal clip that is configured to shield the EM sensitive component from EM fields.

In semiconductor devices, a copper clip is used for electrically connecting a semiconductor die to a lead frame. Copper clips are commonly used for high power devices. For example, the copper clips are used in the packaging of power semiconductor device, such as a power field-effect transistor (FET) (e.g., a metal-oxide-semiconductor FET (MOSFET) and an insulated-gate bipolar transistor (IGBT), where relatively high current and relatively high temperature operation is called for. However, the metal clips disclosed herein can be electrically isolated from the SMT component disposed between the metal clip and a carrier such that the metal clip do not provide electrical connection between the carrier and the SMT component that is mounted on the carrier.

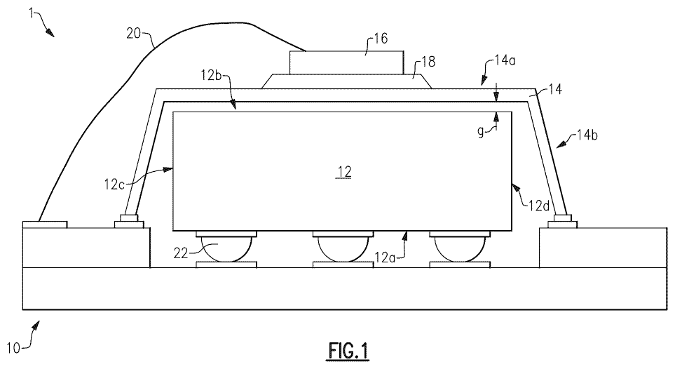

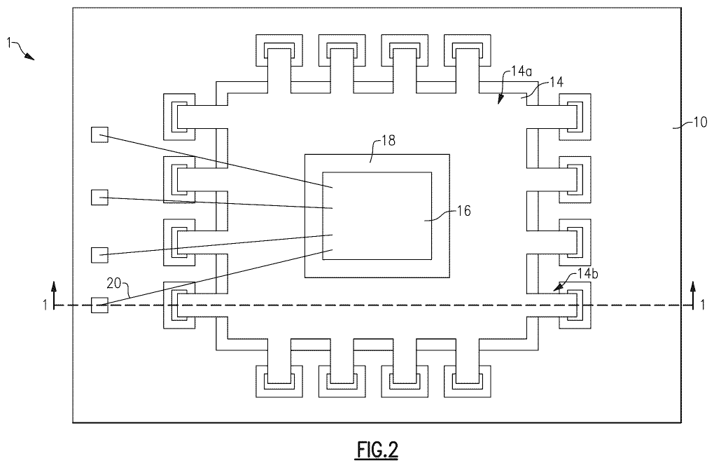

FIG. 1 is a schematic cross-sectional side view of an integrated device package 1 according to an embodiment. FIG. 2 is a schematic top plan view of the integrated device package 1 of FIG. 1. The integrated device package 1 can include a carrier 10, a surface mount technology (SMT) component 12 that is flip-chip mounted on the carrier 10, a metal clip 14 that is coupled to the carrier 10, and an electronic component 16 mounted to a first portion (e.g., a plate portion 14a) of the metal clip 14 by way of an adhesive 18. The electronic component 16 can be electrically connected to the carrier 10 by way of a bond wire 20.

The carrier 10 can be any suitable carrier for receiving the SMT component 12. For example, the carrier 10 can be a laminate substrate, such as a printed circuit board (PCB) or a leadframe. In some embodiments, the PCB can include a material such as an FR-1 material, an FR-4 material, a CEM-1 material, a CEM-3 material, or polyimide.

In some embodiments, the SMT component 12 can be mounted to the carrier 10 by way of solder balls 22. In some applications, the SMT component 12 can be a mechanically sensitive component, such as a gallium arsenide (GaAs) die or a bulk acoustic wave (BAW) filter. In some other applications, the SMT component 12 can be an electromagnetically sensitive component. As illustrated in FIG. 1, the SMT component 12 and the metal clip 14 are spaced apart by a gap g. In some embodiments, the gap g can be sufficiently distanced so as to prevent or mitigate the plate portion 14a of the metal clip 14 from contacting the SMT component 12, while relatively small so as to avoid a significant increase in a total thickness of the integrated device package 1. For example, the gap g can be in a range of 10 μm to 200 μm, 10 μm to 100 μm, 20 μm to 200 μm, or 50 μm to 100 μm. The metal clip 14 can be electrically isolated from the SMT component 12 such that there is no electrical communication between the metal clip 14 and the SMT component 12.

The metal clip 14 includes the first portion (the plate portion 14a) and a second portion (e.g., one or more legs 14b). The SMT component 12 can include a lower side 12a facing the carrier 10, an upper side 12b opposite the lower side 12a, a first sidewall 12c extends between the lower side 12a and the upper side 12b, and a second sidewall 12d opposite the first sidewall 12c. The second portion (the plate portion 14a) of the metal clip includes a first leg disposed adjacent to the first sidewall 12c and a second leg disposed adjacent to the second sidewall 12d.

The one or more legs 14b can be connected to the carrier 10 and extend between the carrier 10 and the plate portion 14a. At least a portion of the plate portion 14a can be disposed over the SMT component 12 and receive the electronic component 16. Accordingly, the metal clip 14 enables the electronic component 16 to be disposed or stacked over the SMT component 12 without negatively affecting the performance of the SMT component 12. Therefore, the metal clip 14 can function as a support structure for the electronic component 16.

In some embodiments, the metal clip 14 can be grounded. In such embodiments, the one or more legs 14b of the metal clip 14 can be connected to a ground line of the carrier 10. The metal clip 14 can provide a ground connection for the electronic component 16.

In some embodiments, the metal clip 14 can be structured so as to function as an electromagnetic (EM) shield. For example, the metal clip 14 can sufficiently encase the SMT component 12 so as to shield the SMT component 12 from EM fields. The metal clip 14 can partially or completely encase the SMT component 12.

As illustrated in FIG. 2, the metal clip 14 can include the one or more legs 14b on all sides of the plate portion 14a. However, in some embodiments, the metal clip 14 may include the one or more legs 14b only on selected side(s) of the plate portion 14a. Also, a number (e.g., sixteen legs shown in FIG. 2), a size (e.g., width and length), and/or a shape of the one or more legs 14b can be selected in any suitable manner. For example, the number, the size, and/or the shape of the one or more legs 14b can be selected to provide sufficient structural support to receive the electronic component 16, to provide sufficient ground for the electronic component 16, and/or to provide sufficient EM shielding for the SMT component 12. In some embodiments, the metal clip 14 can be formed from a sheet of metal, such as a single sheet of copper (Cu). Therefore, the plate portion 14a and the one or more legs 14b can be unitary formed and the metal clip 14 can have a unitary structure.

The electronic component 16 can include any suitable component. For example, the electronic component 16 can be a passive component or an active component. For example, the electronic component 16 can be an amplifier (e.g., a low-noise amplifier (LNA)), or a complementary metal-oxide-semiconductor (CMOS) component.

The adhesive 18 can include a suitable conductive or nonconductive material, such as a die mount paste, die attach film (DAF), or a conductive die attach film (cDAF). When the adhesive 18 includes a conductive material, the electronic component 16 can be electrically connected to the metal clip 14 through the adhesive 18. In some embodiments, the metal clip 14 and the adhesive 18 can at least partially provide a ground connection between the carrier 10 and the electronic component 16.

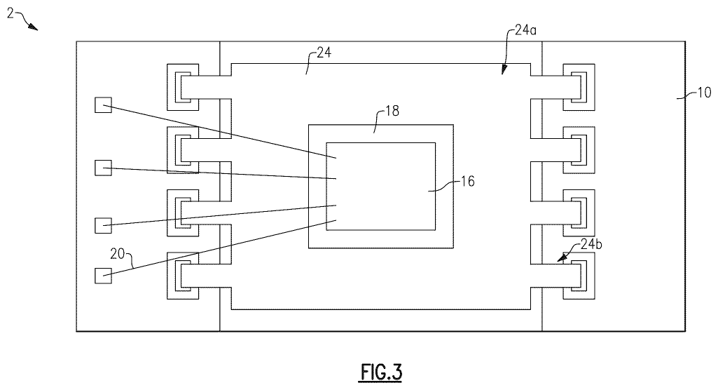

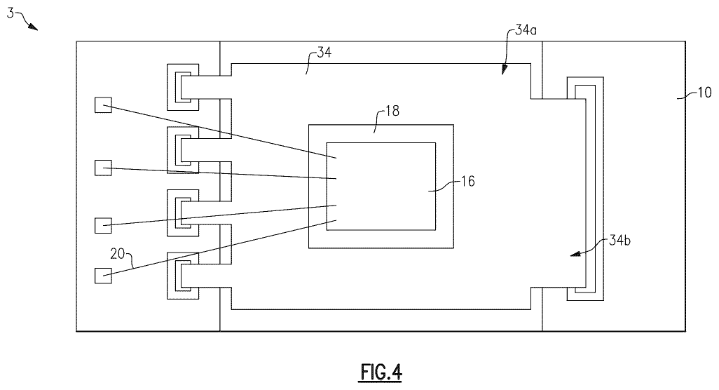

FIGS. 3 and 4 are schematic top plan views of integrated device packages 2, 3 according to some embodiments. FIGS. 3 and 4 show variations of the metal clip 14 as metal clips 24, 34. The integrated device packages 2, 3 can be generally similar to the integrated device package 1 illustrated in FIGS. 1 and 2.

The metal clip 24 includes a plate portion 24a and one or more legs 24b that are disposed on two opposing sides of the plate portion 24a. As compared to a size of the integrated device package 1 of FIGS. 1 and 2 that includes the metal clip 14, the metal clip 24 can reduce a lateral size of the integrated device package 2.

The metal clip 34 includes a plate portion 34a and one or more legs 34b that are disposed on two opposing sides of the plate portion 24a. The one or more legs 34b of the metal clip 34 illustrated in FIG. 4 can include four narrower legs and a wider leg. The number, the size, and/or the shape of the one or more legs 24b, 34b can be selected to provide sufficient structural support to receive the electronic component 16, to provide sufficient ground for the electronic component 16, and/or to provide sufficient EM shielding for the SMT component 12. Therefore, the structural examples of the metal clips 14, 24, 34 are not limited to those shown herein.

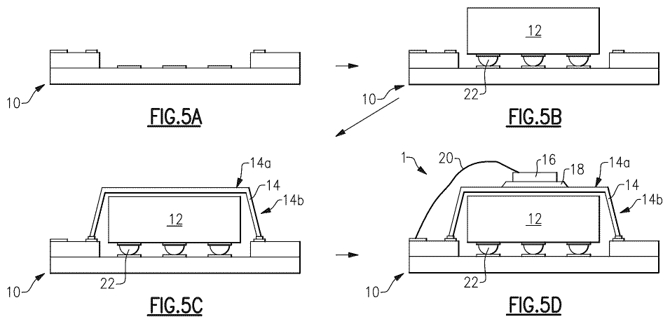

FIGS. 5A-5D show an example of a method or manufacturing the integrated device package 1 according to one embodiment. In FIG. 5A, a carrier 10 can be provided. The carrier 10 can be a substrate, such as a printed circuit board (PCB). In FIG. 5B, a surface mount technology (SMT) component 12 can be provided. In some embodiments, the SMT component 12 can be flip-chip mounted to the carrier 10 by way of solder balls 22. In FIG. 5C, a metal clip 14 can be provided. The metal clip 14 can have a plate portion 14a and one or more legs 14b. The metal clip 14 can be provided such that at least a portion of the plate portion 14a is disposed over the SMT component 12, and ends of the one or more legs 14b are coupled to the carrier 10. In some embodiments, the ends of the one or more legs 14b can be connected to a ground line provided with the carrier 10. In some embodiments, the metal clip 14 can be formed from a sheet of metal (e.g., copper (Cu)), such as a single sheet of metal. In some other embodiments, the metal clip can be formed by coupling one or more metal pillar and a plate of metal, or etching a portion of a bulk metal away. In some embodiments, forming the metal clip may include a plating process. In FIG. 5D, an electronic component 16 can be provided. In some embodiments, the electronic component 16 can be mounted to the plate portion 14a of the metal clip 14 by way of an adhesive 18. The electronic component 16 can be wire bonded to the carrier by way of bond wires 20. In some embodiments, at least a portion of the integrated device package 1 can be overmolded by a molding material (not shown).

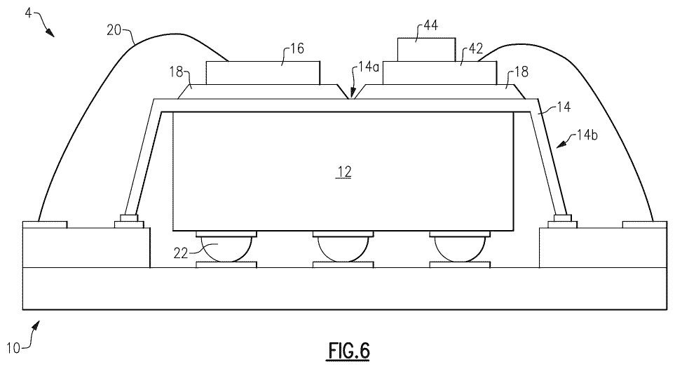

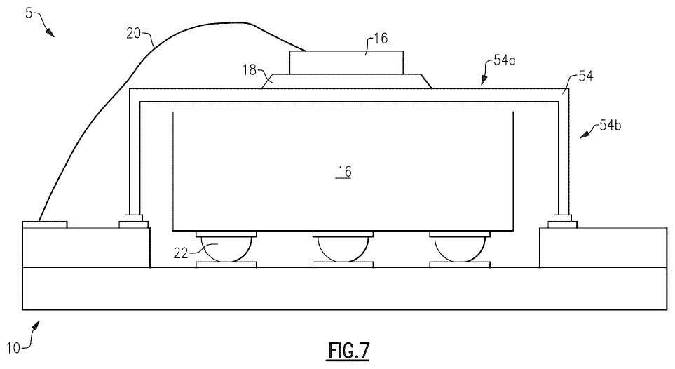

FIGS. 6 and 7 show variations of the integrated device package 1 as integrated device packages 4, 5. FIG. 6 is a schematic cross-sectional side view of the integrated device package 4 according to one embodiment. Unless otherwise noted, components of FIG. 6 can be the same as or generally similar to like components disclosed herein, for example, in FIGS. 1 and 2. The integrated device package 4 is generally similar to the integrated device package 1 of FIGS. 1 and 2 except that the integrated device package 4 includes a plurality of electronic components 16, 42, 44 over the SMT component 12, and the metal clip 14 of the integrated device package 4 is in contact with the SMT component 12.

The plurality of electronic components 16, 42, 44 can be bonded to the plate portion 14a of the metal clip 14 by way of adhesives 18. In some embodiments, as shown in FIG. 6, the electronic component 16 and the electronic components 42, 44 can be laterally positioned, and the electronic component 44 can be stacked over the electronic component 42. One or more of the electronic components 16, 42, 44 can be wire-bonded to the carrier by way of bond wires.

The metal clip 14 of the integrated device package 4 is in contact with the SMT component 12. In other words, a gap g between the metal clip 14 and the SMT component 12 is zero in the integrated device package 4. The metal clip 14 can be electrically isolated from the SMT component 12 such that there is no electrical communication between the metal clip 14 and the SMT component 12. A skilled artisan will understand that, as described with respect to FIG. 1, the SMT component 12 and the metal clip 14 may be spaced apart.

FIG. 7 is a schematic cross sectional side view of the integrated device package 5 according to one embodiment. Unless otherwise noted, components of FIG. 7 can be the same as or generally similar to like components disclosed herein, for example, in FIGS. 1 and 2. The integrated device package 5 is generally similar to the integrated device package 1 of FIGS. 1 and 2 except that the metal clip 54 of the integrated device package 5 includes one or more pillars 54b as the one or more legs 14b of the metal clip 14.

Various embodiments of the integrated device packages disclosed herein may be implemented in any suitable electronic devices such as an acoustic wave device (e.g., mobile phone). One or more features of the integrated device packages disclosed herein can be combined or omitted in accordance with a desired specification.

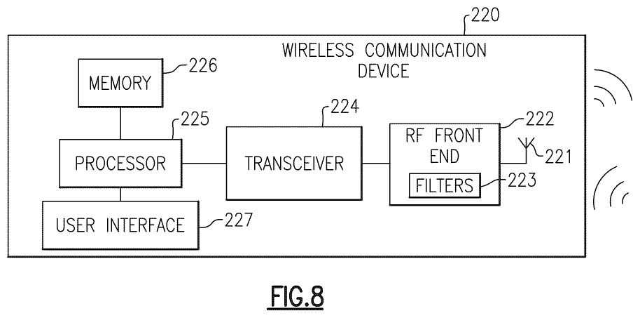

FIG. 8 is a schematic diagram of a wireless communication device 220 As illustrated, the wireless communication device 220 includes an antenna 221, a radio frequency (RF) front end 222, a transceiver 224, a processor 225, a memory 226, and a user interface 227. The wireless communication device 220 can include filters 223 in the RF front end 222. The filters 223 can include one or more bulk acoustic wave (BAW) resonators. The wireless communication device 220 can be any suitable wireless communication device. For instance, a wireless communication device 220 can be a mobile phone, such as a smart phone. The antenna 221 can transmit/receive RF signals provided by the RF front end 222. Such RF signals can include carrier aggregation signals. Although not illustrated, the wireless communication device 220 can include a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An integrated device package comprising:
a surface mount technology component flip-chip mounted to a carrier;
a metal clip having a first portion at least partially disposed over the surface mount technology component and a second portion coupled to the carrier, the first portion and the surface mount technology component spaced apart by a gap; and
an electronic component mounted to the first portion of the metal clip.

2. The integrated device package of claim 1 wherein the surface mount technology component is a gallium arsenide die or a bulk acoustic wave filter.

3. The integrated device package of claim 1 wherein the carrier is a printed circuit board.

4. The integrated device package of claim 1 wherein the gap between the first portion and the surface mount technology component is in a range of 10 micrometers to 200 micrometers.

5. The integrated device package of claim 1 wherein the metal clip is connected to a ground.

6. The integrated device package of claim 1 wherein the metal clip is an electromagnetic shield configured to shield the surface mount technology component from electromagnetic fields.

7. The integrated device package of claim 1 wherein the metal clip is a copper clip.

8. The integrated device package of claim 7 wherein the first portion and the second portion are unitary formed.

9. The integrated device package of claim 1 wherein the electronic component is mounted to the first portion of the metal clip by way of a die mount paste, a die attach film, or a conductive die attach film such that the first portion is positioned between the surface mount technology component and the electronic component.

10. The integrated device package of claim 1 wherein the electronic component is wire bonded to the carrier.

11. The integrated device package of claim 1 further comprising a second electronic component mounted to the first portion of the metal clip.

12. An integrated device package comprising:
a bulk acoustic wave filter mounted to a carrier;
a metal clip having a first portion at least partially disposed over the bulk acoustic wave filter and second portion coupled to the carrier, the first portion and the bulk acoustic wave filter spaced apart by a gap; and
an electronic component mounted to the first portion of the metal clip.

13. The integrated device package of claim 12 wherein the bulk acoustic wave filter is flip-chip mounted to the carrier.

14. The integrated device package of claim 12 wherein the carrier is a printed circuit board.

15. The integrated device package of claim 12 wherein the gap between the first portion and the bulk acoustic wave filter is in a range of 10 micrometers to 200 micrometers.

16. The integrated device package of claim 12 wherein the first portion and the second portion are unitary formed.

17. An integrated device package comprising:
a surface mount technology component mounted to a printed circuit board;
a metal clip having a first portion at least partially disposed over the surface mount technology component and a second portion coupled to the printed circuit board, the first portion and the surface mount technology component spaced apart by a gap; and
an electronic component mounted to the first portion of the metal clip.

18. The integrated device package of claim 17 wherein the surface mount technology component is a bulk acoustic wave filter that is flip-chip mounted to the printed circuit board.

19. The integrated device package of claim 17 wherein the gap between the first portion and the surface mount technology component is in a range of 10 micrometers to 200 micrometers.

20. The integrated device package of claim 17 wherein the first portion and the second portion are unitary formed.
